(19) United States
(12) Patent Application Publication
(10) Pub. No.: US 2008/0237659 A1
(43) Pub. Date: Oct. 2, 2008

(54) SEMICONDUCTOR DEVICE AND METHOD OF FABRICATING THE SAME

(75) Inventor: Chin-Sheng Yang, Hsinchu (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/691,708

(22) Filed: Mar. 27, 2007

(51) Int. Cl. H01L 29/94; H01L 21/00; H01L 21/336

(52) U.S. Cl. 257/288; 438/106; 438/197; 257/E21.002; 257/E21.409; 257/E29.345

(57) ABSTRACT

A method of fabricating a semiconductor device is provided. Devices are formed on a core region and a non-core region in a substrate. A strain process is performed to the device on the core region but is not performed to the device on the non-core region.

### BACKGROUND OF THE INVENTION

1. Field of Invention

The present invention relates to an integrated circuit and a method for fabricating the same. More particularly, the present invention relates a semiconductor device and a method for fabricating the same.

2. Description of Related Art

Along with the development of the technology in electronic equipments for communication, etc., the operating speed of a transistor increases rapidly. However, limited by the mobility rate of electrons and holes in the silicon channel, the area of application of the transistor is limited.

Relying on the mechanical stress in the channel to control the mobility rate of electrons and holes in the channel is one approach to enhance the operational speed of a transistor.

Conventionally, the silicon germanium (SiGe) type of material has been proposed for forming the source/drain regions of the transistor, wherein portions of the substrate pre-determined for forming the source/drain regions are removed. Thereafter, a selective area epitaxial growth technique is applied to fill the substrate with silicon germanium. Since germanium has a larger atom size to impose a compressive stress to the channel, using a silicon germanium material for the source/drain regions enhances the mobility of holes, when compared with a silicon material. Another approach is by using silicon nitride as a contact etching stop layer (CESL) to generate stress for influencing the driving current of the transistor. As a result, the efficiency of the device is increased. This technique is known as local mechanical-stress control.

However, the above-mentioned approaches are concurrently performed to the substrate of the core circuit region and the non-core circuit region. The electrical properties of the devices in the non-core circuit region are altered, and thus become different from the original design, resulting in operational problems of the device.

### SUMMARY OF THE INVENTION

The present invention is to provide a semiconductor device and a fabrication method thereof, wherein the efficiency of the devices in the core circuit is enhanced, while the electrically properties of the devices in the non-core circuit region are maintained.

The present invention is to provide a semiconductor device and a fabrication method thereof, wherein devices are respectively formed on the substrate of the core circuit region and the non-core circuit region. Further, a strain process is performed to the devices in the core circuit region but not to the devices in the non-core circuit region.

According to the fabrication method of a semiconductor device of an embodiment of the present invention, the core circuit region includes a low voltage device region, while the non-core circuit region includes a switching device region, an electrostatic discharge protection region, a high voltage device region and other combinations of regions.

According to the fabrication method of a semiconductor device of an embodiment of the present invention, the core circuit region or the non-core circuit region can selectively include a medium voltage device region, a high speed device region, a standard efficiency device region or a low leakage current device region.

According to the fabrication method of a semiconductor device of an embodiment of the present invention, the strain process includes forming a source/drain region in the core circuit region using a semiconductor compound layer or forming a stress layer on the device of the core circuit region.

According to the fabrication method of a semiconductor device of an embodiment of the present invention, the devices of the core circuit region includes a first conductive type metal oxide semiconductor device and a second conductive type metal oxide semiconductor device. The strain process includes forming a stress layer on the first conductive type metal oxide semiconductor device but not on the second conductive type metal oxide semiconductor device; and/or forming the source/drain region of the second conductive type metal oxide semiconductor device with a semiconductor compound layer, while forming the source/drain region of the first conductive type metal oxide semiconductor device with a material the same as that of the substrate.

According to the fabrication method of a semiconductor device of an embodiment of the present invention, the first conductive type includes an n-type, while the second conductive type includes a p-type.

According to the fabrication method of a semiconductor device of an embodiment of the present invention, the stress layer includes a tensile stress layer.

According to the fabrication method of a semiconductor device of an embodiment of the present invention, the tensile stress layer includes a contact etching stop layer (CESL).

According to the fabrication method of a semiconductor device of an embodiment of the present invention, the semiconductor compound layer includes a silicon germanium layer.

According to the fabrication method of a semiconductor device of an embodiment of the present invention, the devices of the core circuit region include a first conductive type metal oxide semiconductor (MOS) device and a second conductive type metal oxide semiconductor device. The strain process includes forming a first stress layer on the first conductive type metal oxide semiconductor device but not on the second conductive type metal oxide semiconductor device; and/or forming a second stress layer on the second conductive type metal oxide semiconductor device but not on the first conductive type metal oxide semiconductor device.

According to the fabrication method of a semiconductor device of an embodiment of the present invention, the device of the core circuit region, the first conductive device of the core circuit region includes an n-type, while the second conductive device includes a p-type device. The first stress layer includes a tensile stress layer, while the second stress layer includes a compressive stress layer.

According to the fabrication method of a semiconductor device of an embodiment of the present invention, the tensile stress layer of the device of core circuit region includes a contact etching stop layer.

The present invention provides a semiconductor device including a substrate, wherein the substrate includes a core circuit region and a non-core circuit region, a plurality of first conductive type metal oxide semiconductor devices, respectively configured on the core circuit region and the non-core circuit region, wherein the material of the source/drain region of each first conductive type semiconductor device is the same as that of the substrate. Further, a plurality of second conductive type metal oxide semiconductor devices is respectively configured on the core circuit region and the non-core circuit region, wherein a material that constitutes the source/drain region of the second conductive type MOS semiconductor device of the core circuit region is a semiconductor compound, while a material that constitutes the source/drain region of the second conductive type semiconductor device is the same as that of the substrate. Moreover, a stress layer is formed covering the first conductive type MOS device on the core circuit region, while exposing the second conductive type MOS device on the core circuit region and the first and the second conductive type MOS devices of the non-core circuit region.

According to the semiconductor device of an embodiment of the present invention, the core circuit region includes a low voltage device region, while the non-core circuit region includes a switching device region, an electrostatic discharge protection region, a high voltage device region and other combinations of regions.

According to the semiconductor device of an embodiment of the present invention, the core circuit region or the non-core circuit region may selectively include a medium voltage device region, a high speed device region, a standard efficiency device region or a low leakage current device region.

According to the semiconductor device of an embodiment of the present invention, the first conductive type includes an N-type, while the second conductive type includes a P-type.

According to the semiconductor device of an embodiment of the present invention, the stress layer includes a tensile stress layer.

According to the semiconductor device of an embodiment of the present invention, the tensile stress layer includes a contact etching stop layer.

According to the semiconductor device of an embodiment of the present invention, the semiconductor compound includes silicon germanium.

The present invention provides a semiconductor device, wherein the semiconductor device includes a substrate that further includes a core circuit region and a non-core circuit region; a plurality of first conductive type metal oxide semiconductor (MOS) devices, respectively configured on the core circuit region and the non-core circuit region; a plurality of second conductive type MOS devices, respectively configured on the core circuit region and the non-core circuit region; a first stress layer, covering the first conductive type MOS device of the core circuit region, while exposing the second conductive type MOS device of the core circuit region and the first and second conductive types MOS devices of the non-core circuit region; and a second stress layer, covering the second conductive type MOS device of the core circuit region, while exposing the first conductive type MOS of the core circuit region and the first and second conductive types MOS devices of the non-core circuit region.

According to the semiconductor device of an embodiment of the present invention, wherein the first conductive type includes an N-type, while the second conductive type includes a P-type; the first stress layer includes a tensile stress layer, while the second stress layer includes a compressive stress layer.

According to the semiconductor device of an embodiment of the present invention, wherein the tensile stress layer is a contact etching stop layer.

According to the semiconductor device of an embodiment of the present invention, wherein the compressive stress layer is a contact etching stop layer.

According to the semiconductor device of an embodiment of the present invention, the core circuit includes a low voltage device region, while the non-core circuit region includes a switching device region, an electrostatic discharge protection region, a high voltage device region and other combinations of regions.

According to the semiconductor device of an embodiment of the present invention, the core circuit region or the non-core circuit region may selectively include a medium voltage device region, a high speed device region, a standard efficiency device region or a low leakage current device region.

According to the semiconductor device and a fabrication method thereof of the present invention, the efficiency of the devices of the core circuit is enhanced, while the electrical properties of the devices of the non-core circuit region are maintained.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A to 1E are cross-sectional views showing selected process steps for fabricating a semiconductor device according an embodiment of the invention.

FIGS. 2A to 2D are cross-sectional views showing selected process steps for fabricating a semiconductor device according an embodiment of the invention.

### DESCRIPTION OF EMBODIMENTS

According to a fabrication method of a semiconductor device of the present invention, a strain process is performed on the devices of the core circuit region, but not on the devices of the non-core circuit region to enhance the efficiency of the devices of the core circuit region, while maintain the operational characteristics of the devices of the non-core circuit region. The strain process alters the material of the source/drain region of the core circuit region to a semiconductor compound, and/or forms a stress layer on the devices of the core circuit region.

The present invention is illustrated by the following two embodiments. However, it is to be understood that these embodiments are presented by way of example and not by way of limitation.

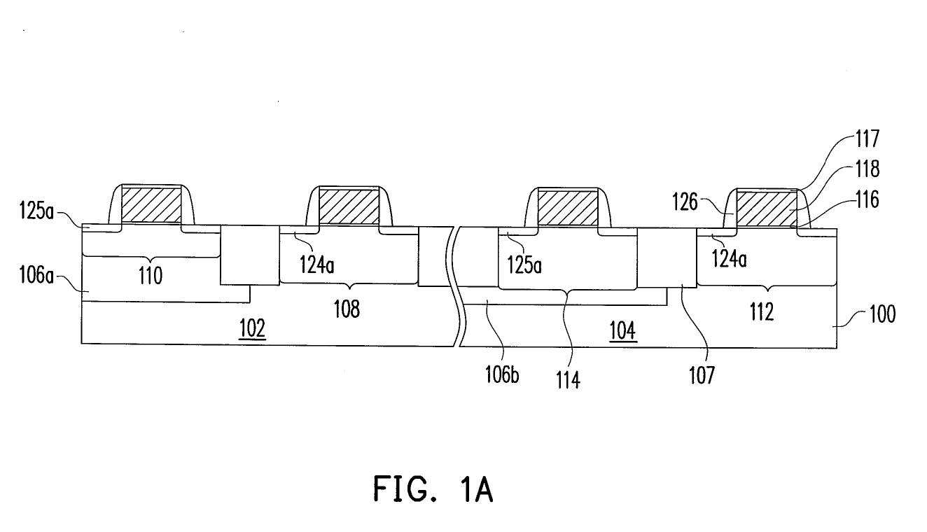

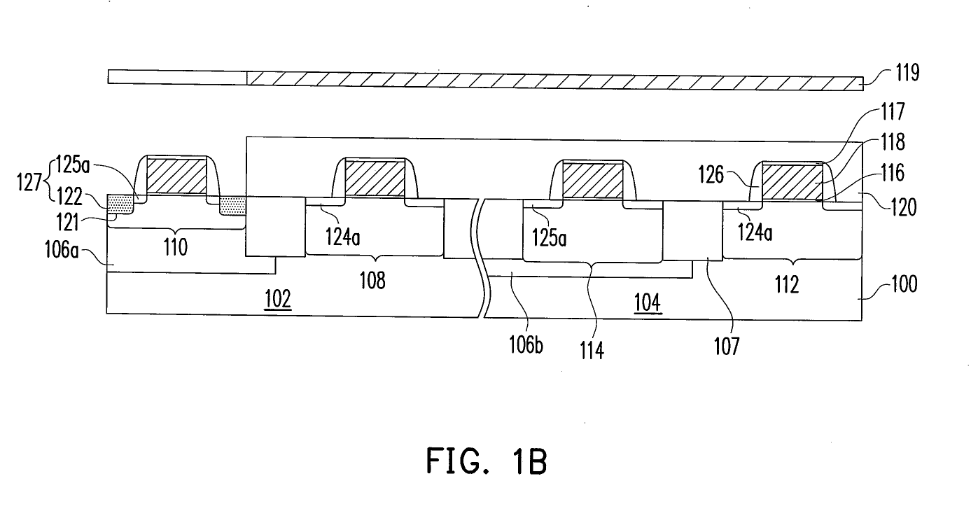

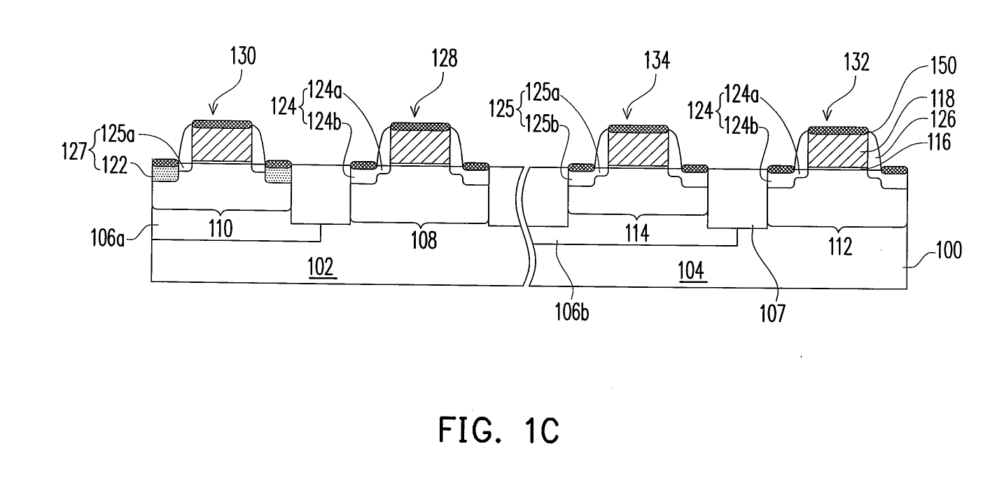

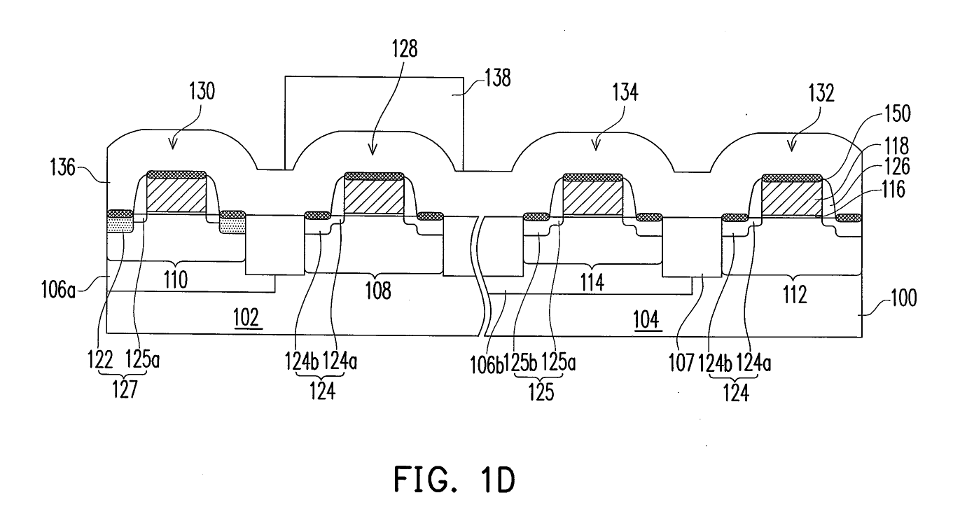

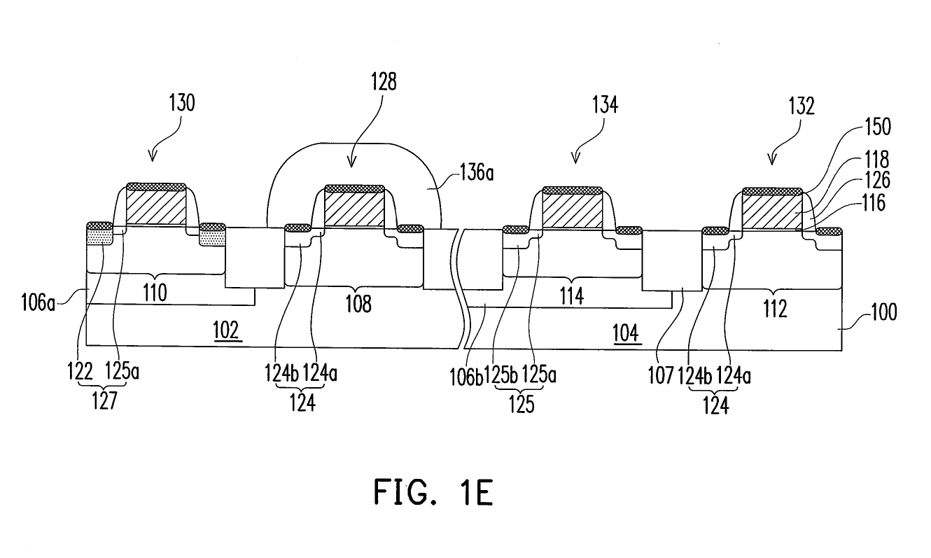

FIGS. 1A to 1E are cross-sectional views showing selected process steps for fabricating a semiconductor device according an embodiment of the invention.

Referring to FIG. 1A, a substrate 100 is provided, wherein a material constituting the substrate 100 includes semiconductor such silicon or silicon-on-insulator (SOI). In one embodiment, the substrate is p-type doped silicon, for example. The substrate 100 includes a core circuit region 102 and a non-core circuit region 104. The core circuit region 102 includes, for example, a low voltage device region. The non-core circuit region 104 includes, for example, a switching device region, an electrostatic discharge protection region, a high voltage device region and combinations of the above regions. The core circuit region 102 or the non-core circuit region 104 can optionally includes a medium voltage device region, a high speed device region, a standard efficiency device region or a low leakage current device region.

N-type doped well regions 106a, 106b are respectively formed in the substrate 100 of the core circuit region 102 and the non-core circuit region 104. Isolation trench structures 107 are further formed in the substrate 100 to define an NMOS device region 108, a PMOS device region 110, and an NMOS device region 112, a PMOS device region 114, respectively in the core circuit region 102 and the non-core circuit region 104. The isolation structures 107 are formed by shallow trench isolation or local oxidation, for example.

Thereafter, gate dielectric layers 116, gate electrodes 118 and cap layers 117 are formed respectively in the NMOS device region 108, the PMOS device region 110, and the NMOS device region 112, the PMOS device region 114. The gate dielectric layers are formed with silicon oxide, for example, by methods including but not limited to thermal oxidation. The gate electrodes 118 are formed with a silicon material, including but not limited to doped silicon, undoped silicon, doped polysilicon, or undoped polysilicon. When the gate electrodes 118 are formed with doped silicon or doped polysilicon, the dopants in the silicon or polysilicon can be n-type dopants or p-type dopants. The material that constitutes the cap layer 117 includes silicon oxide, formed by chemical vapor deposition, for example.

An n-type doping mask and a p-type doping mask are respectively formed on the substrate 100. Ion implantation processes are respectively performed to form an n-type source/drain extension region 124a on the NMOS device regions 108 and 112 and to form a p-type source/drain extension region 125a on the PMOS device regions 110 and 114. Thereafter, a spacer 126 is formed the sidewall of each gate electrode 118. The spacer 126 can be a single layer spacer or a double layer spacer.

Referring to FIG. 1B, a strain process is performed on the core circuit region 102. A mask layer 110 is initially formed over the substrate 100, covering the NMOS device region 108 of the core circuit region 102, and the NMOS device region 112 and the PMOS device region 114 of the non-core circuit region 104, while exposing the PMOS device region 110 of the core circuit region 102. The mask layer 120 is formed by forming a photoresist layer over the substrate 100. Subsequent to an exposure process, the pattern on the photomask 119 is transferred to the photoresist layer, which is being patterned after a development process.

Using the mask layer 120 as an etching mask, the substrate 100 beside two sides of the gate electrode 118 in the PMOS device region 110 to form a cavity 121. A selective area epitaxy growth process is then performed to the cavity 121 to grow epitaxially a semiconductor compound layer 122 and the semiconductor compound layer is doped to form a source/drain region. The semiconductor compound includes silicon germanium. Silicon germanium is formed by introducing a silicon-containing gas source such as silicon hydride (SiH₄), dichloromethane (CH₂Cl₂) or a mixture thereof, a germanium-contain gas source such as germane (GeH₄), hydrochloric acid (HCl) and a doped gas source such as borane (BH₃) as a reacting gas source to the chemical vapor deposition reaction chamber, and performing the deposition process for about 3 to 4 hours under a temperature of about 700 to 900° F. During the deposition process, an in-situ doping may perform with p-type dopants, such as boron, to form the source/drain contact region 122. The source/drain contact region 122 and the source/drain extension region 125a constitute a source/drain region 127.

Continuing to FIG. 1C, the mask layer 120 is removed. An n-type doping mask and a p-type doping mask are respectively formed on the substrate 100. Thereafter, an ion implantation process is performed to form the source/drain contact regions 124b, which in combination with the source/drain extension regions 124a constitute the source/drain regions 124 in the NMOS device region 108 of the core circuit region 102 and the NMOS device region 112 of the non-core circuit region 104, respectively. A source/drain contact region 125b is also formed in the PMOS device region of the non-core circuit region 104 to form a source/drain contact region 125b, which in combination with the source/drain extension region 125a constitutes a source/drain region 125.

The cap layer 117 is subsequently removed, for example, by performing wet etching using a hydrofluoric acid solution. A silicide layer 150 is further formed on the source/drain regions 124, 125, 127 and the gate electrodes 118. The silicide layer 150 includes fire-tolerant metal silicide such as, nickel, cobalt, copper, molybdenum, tantalum, tungsten, erbium, zirconium, platinum, or alloy thereof.

An NMOS device 128, a PMOS device 130 and an NMOS device 132, a PMOS device 134 are respectively formed in the NMOS device region 108, the PMOS device region 110 and the NMOS device region 112, the PMOS device region 114.

As shown in FIG. 1D, a stress layer 136 is formed on the substrate 100. The stress layer 136 is a tensile stress layer, for example. The tensile stress layer can be a contact etching stop layer (CESL). The stress layer 136 is constituted with a material including silicon nitride, and is formed by chemical vapor deposition, for example. Hereafter, a mask layer 138 is formed on the substrate 100. The mask layer 138 covers the stress layer 136 on the NMOS device region 108 of the core circuit region 102, while exposes the stress layer 136 on the PMOS device region 110 of the core circuit region 102, and the NMOS device region 112 and the PMOS device region 114 of the non-core circuit region 104. The mask layer 138 is formed by forming a photoresist layer on the substrate 100, followed by patterning the photoresist layer via exposure and development.

Referring to FIG. 1E, using a mask layer 138 as an etching mask, the exposed stress layer 136 is etched, leaving behind the stress layer 136a on the NMOS device region 108. The exposed stress layer 136 is etched by performing an anisotropic etching process, for example. Thereafter, the mask layer 138 is removed.

In this embodiment, the strain process includes forming the source/drain region of the PMOS device in the core circuit region with a semiconductor compound, such as silicon germanium, and forming a tensile stress layer on the NMOS device of the core circuit region. Ultimately, the efficiency of the devices in the core circuit region is improved while the operational characteristics of the devices in non-core circuit region are maintained.

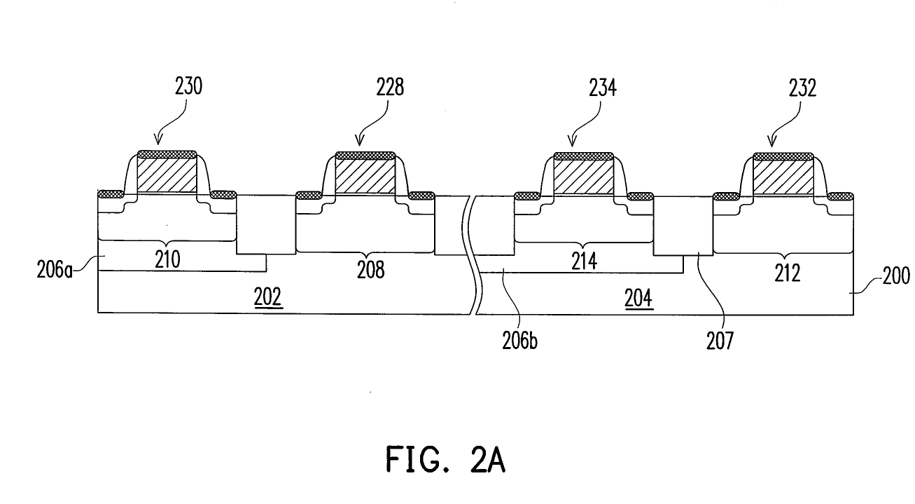

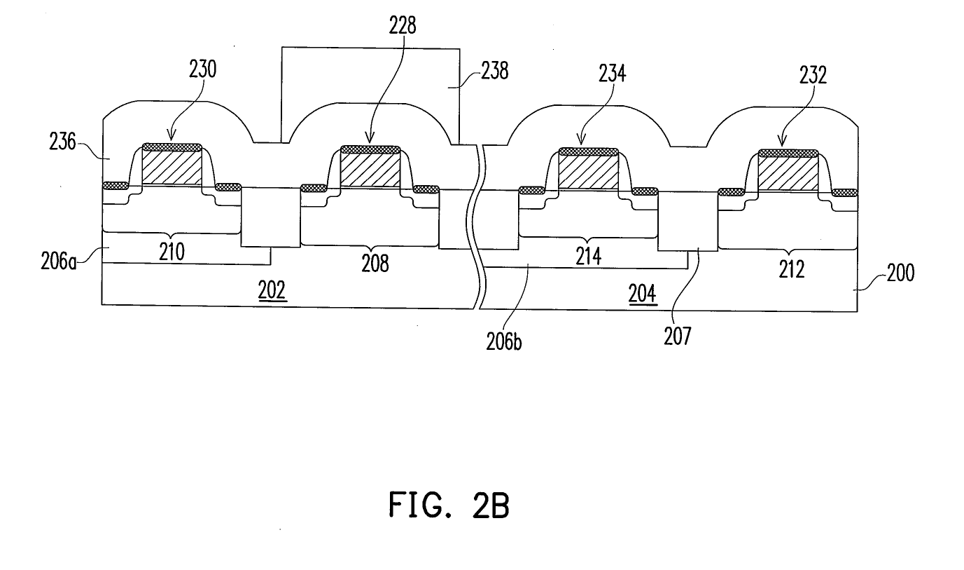

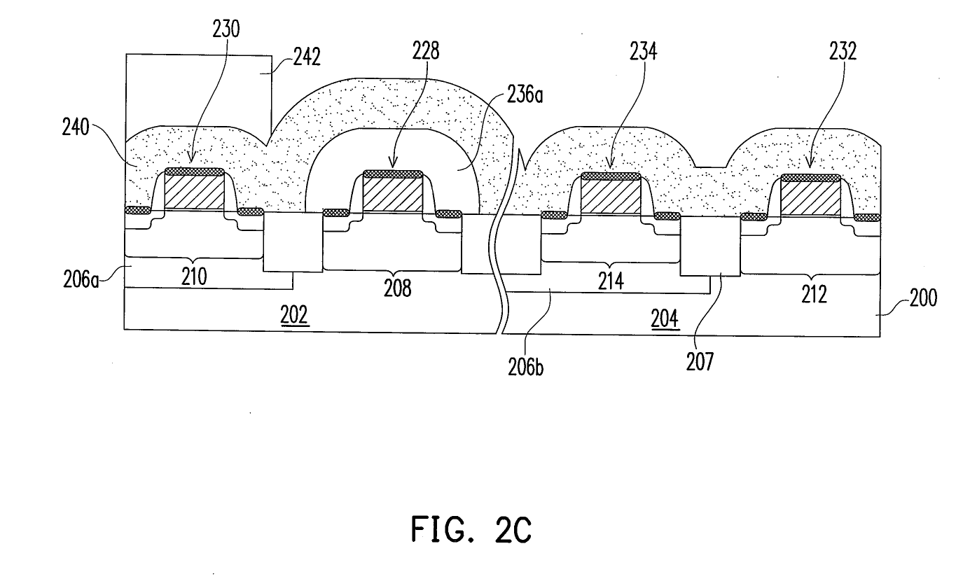

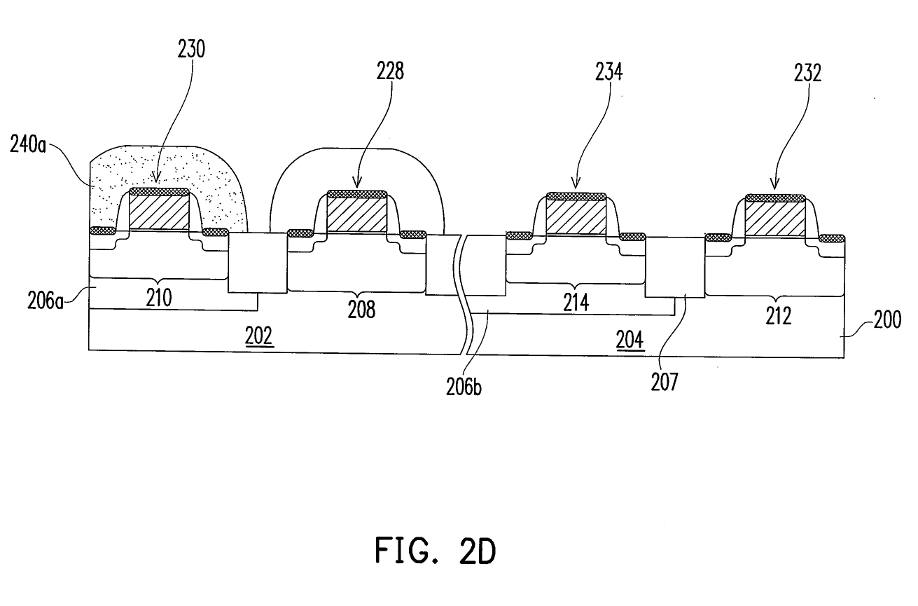

FIGS. 2A to 2D are cross-sectional view showing selected process steps for fabricating a semiconductor device according an embodiment of the invention.

Referring to FIG. 2A, a substrate 200 is provided, wherein a material that constitutes the substrate 200 includes a semiconductor such as silicon or silicon-on-insulator. In one embodiment, the substrate 200 includes p-type doped silicon. The substrate 200 includes a core circuit region 202 and a non-core circuit region 204. The core circuit region 202 includes but not limited to a low voltage device region. The non-core circuit region 204 includes a switching device region, an electrostatic discharge region, a high voltage device region and combinations of the above regions. The core circuit region or the non-core circuit region may optionally include a medium voltage region, a high-speed device region, a standard efficiency device region or a low leakage current device region.

N-type doped well regions 206a and 206b are respectively formed in the substrate 200 of the core circuit region 202 and the non-core circuit region 204. Thereafter, isolation trenches 207 are formed in the substrate 200 to define a NMOS device region 208, a PMOS device region 210 and a NMOS device region 212, a PMOS device region 214, respectively in the core circuit region 202 and the non-core circuit region 204. The isolation trenches 207 are formed by methods including shallow trench isolation or local oxidation.

In the meantime, an NMOS device 228, a PMOS device 230 and an NMOS device 232, a PMSO device 234 are respectively formed in the NMOS device region 208, the PMOS device region 210, and the NMOS device region 212, the PMOS device region 214.

Referring to FIG. 2B, a strain process is performed on the core circuit region 102. A tensile stress layer 236 is formed on the substrate 200. The tensile stress layer 236 is a contact etching stop layer, for example. The tensile stress layer 236 is constituted with a material including silicon nitride, and is formed by chemical vapor deposition, for example. Thereafter, a mask layer 238 is formed on the substrate 200. The mask layer 238 covers the stress layer 236 on the NMOS device region 208, while exposes the tensile stress layer 236 on the PMOS device region 210, the NMOS device region 212 and the PMOS device region 214. The mask layer 238 is formed by forming a photoresist layer on the substrate 200, followed by patterning the photoresist layer via exposure and development.

Thereafter, referring to FIG. 2C, using the mask layer 238 as an etching mask, the exposed stress layer 236 is etched, leaving the tensile stress layer 236a on the NMOS device region 208. The etching is conducted using anisotropic etching, for example. Thereafter, the mask layer 238 is removed and a compressive stress layer 240 is then formed on the substrate 200. The compressive stress layer 240 includes a contact etching stop layer, for example. The compressive stress layer 240 is constituted with a material include silicon nitride, and is formed by chemical vapor deposition, for example. Thereafter, a mask layer 242 is formed on the substrate. The mask layer 242 covers the compressive stress layer on the PMOS device region 210, while exposes the compressive stress layer 240 on the NMOS device region 208, the NMOS device region 212 and the PMOS device region 214. The mask layer 242 is formed by forming a photoresist layer on the substrate 200, for example, followed by patterning the photoresist layer via exposure and development.

Referring to FIG. 2D, using the mask layer 242 as an etching mask, the exposed stress layer 240 is etched, leaving behind the compressive stress layer 240a on the PMOS device region 210. The etching is conducted using anisotropic etching. Thereafter, the mask layer 242 is removed.

Although the above-mentioned embodiment refers to forming a tensile stress layer on the NMOS device region, followed by forming a compressive stress layer in the PMOS device region, it is to be understood that these embodiments are presented by way of example and not by way of limitation. The compressive stress layer may first form in the PMOS device region, followed by forming a tensile stress layer in the NOMS device region. Further, other methods may apply to form the tensile stress layer and the compressive stress layer, respectively in the NMOS device region and the PMOS device region.

In this embodiment, the strain process includes forming a tensile stress layer on the NMOS device in the core circuit region and forming a compressive stress layer on the PMOS device in the core circuit region to alter the efficiency of the devices in the core circuit region while maintain the operation characteristics of the devices in the non-core circuit region.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of fabricating a semiconductor device, comprising:
providing a substrate, and the substrate comprising a core circuit region and a non-core circuit region;
forming a device on the core circuit region and a device on the non-core circuit region; and
performing a strain process on the device of the core circuit region but not on the device of the non-core circuit region.

2. The method of claim 1, wherein the core circuit region comprises a low voltage device region, while the non-core circuit region comprises a switching device region, an electronstatic discharge region, a high voltage device region or a combination thereof.

3. The method of claim 2, wherein the core circuit region or the non-core circuit region comprises a medium voltage device region, a high-speed device region, a standard efficiency device region or a low leakage current region.

4. The method of claim 1, wherein the strain process comprises using a semiconductor compound as a material of a source/drain region of the device of the core circuit region and/or forming a stress layer on the device of the core circuit region.

5. The method of claim 4, wherein the device of the core circuit region comprises a first conductive type metal oxide semiconductor (MOS) device and a second conductive type metal oxide semiconductor device, and the strain process comprises:
forming a stress layer on the first conductive type MOS device but not on the second conductive type MOS device; and/or
using a semiconductor compound as a material of a source/drain region of the second conductive type MOS device, but using a material of the substrate as a material of a source/drain region of the first conductive type MOS device.

6. The method of claim 5, wherein the first conductive type includes an N-type, and the second conductive type includes a P-type.

7. The method of claim 6, wherein the stress layer includes a tensile stress layer.

8. The method of claim 7, wherein the tensile stress layer includes a contact etching stop layer (CESL).

9. The method of claim 6, wherein the semiconductor compound includes silicon germanium.

10. The method of claim 1, wherein the device of the core circuit region comprises a first conductive type metal oxide semiconductor (MOS) device and a second conductive type metal oxide semiconductor device, and the strain process comprises:
forming a stress layer on the first conductive type MOS device but not on the second conductive type MOS device; and/or
forming a second stress layer on the second conductive type MOS device, but not on the first conductive type MOS device.

11. The method of claim 10, wherein the first conductive type includes an N-type, and the second conductive type includes a P-type, and the first stress layer comprises a tensile stress layer and the second stress layer comprises a compressive stress layer.

12. The method of claim 11, wherein the tensile stress layer comprises a contact etching stop layer.

13. A semiconductor device, comprising:
a substrate, comprising a core circuit region and a non-core circuit region;
a plurality of first conductive type metal oxide semiconductor (MOS) devices, configured respectively on the core circuit region and the non-core circuit region, wherein a material of a source/drain region of each first conductive type MOS device is the same as that of the substrate;
a plurality of second conductive type MOS devices, configured respectively on the core circuit region and the non-core circuit region, wherein a material of a source/drain region of the second conductive type MOS device on the non-core circuit region is the same as that of the substrate; and
a stress layer, covering the first conductive type MOS device on the core circuit region, while exposing the second conductive type MOS device on the core circuit region and the first and the second conductive types MOS devices on the non-core circuit region.

14. The device of claim 13, wherein the core circuit region comprises a low voltage device region, while the non-core circuit region comprises a switching device region, an electronstatic discharge region, a high voltage device region or a combination thereof.

15. The device of claim 14, wherein the core circuit region or the non-core circuit region comprises a medium voltage device region, a high-speed device region, a standard efficiency device region or a low leakage current region.

16. The device of claim 13, wherein the first conductive type includes an N-type, and the second conductive type includes a P-type.

17. The device of claim 16, wherein the stress layer includes a tensile stress layer.

18. The method of claim 17, wherein the tensile stress layer comprises a contact etching stop layer (CESL).

19. The method of claim 16, wherein the semiconductor compound includes silicon germanium.

20. A semiconductor device, comprising:
a substrate, comprising a core circuit region and a non-core circuit region;
a plurality of first conductive type metal oxide semiconductor (MOS) devices, configured respectively on the core circuit region and the non-core circuit region;
a plurality of second conductive type MOS devices, configured respectively on the core circuit region and the non-core circuit region;
a first stress layer, covering the first conductive type MOS device on the core circuit region, while exposing the second conductive type MOS device on the core circuit region and the first and the second conductive types MOS devices on the non-core circuit region; and
a second stress layer, covering the second conductive type MOS device on the core circuit region, while exposing the first conductive type MOS device on the core circuit region and the first and the second conductive types MOS devices on the non-core circuit region.

21. The device of claim 20, wherein the first conductive type includes an N-type, and the second conductive type includes a P-type, and the first stress layer comprises a tensile stress layer and the second stress layer comprises a compressive stress layer.

22. The method of claim 20, wherein the tensile stress layer comprises a contact etching stop layer.

23. The method of claim 20, wherein the compressive stress layer comprises a contact etching stop layer.

24. The device of claim 20, wherein the core circuit region comprises a low voltage device region, while the non-core circuit region comprises a switching device region, an electronstatic discharge region, a high voltage device region or a combination thereof.

25. The device of claim 24, wherein the core circuit region or the non-core circuit region comprises a medium voltage device region, a high-speed device region, a standard efficiency device region or a low leakage current region.
